(19) United States
(12) Patent Application Publication
(10) Pub. No.: US 2006/0152304 A1
(43) Pub. Date: Jul. 13, 2006

(54) Electrically tunable notch filters

(76) Inventors: Xiao-Peng Liang, San Jose, CA (US); Khosro Shamsaifar, Ellicott City, MD (US)

Correspondence Address: James S. Finn, 14431 Goliad Drive, Malakoff, TX, 75148, US

(21) Appl. No.: 11/373,387

(22) Filed: Mar. 10, 2006

Related U.S. Application Data
(63) Continuation of application No. 10/013,265, filed on Dec. 10, 2001.
(60) Provisional application No. 60/254,841, filed on Dec. 12, 2000.

(51) Int. Cl. H03H 7/01

(52) U.S. Cl. 333/176

(57) ABSTRACT

This invention provides a notch filter including a main transmission line, a coupling mechanism, and at least one electrically tunable resonator coupled to the transmission line through the coupling mechanism. A tunable dielectric varactor or a microelectromechanical variable capacitor is provided in each of the resonators.

### CROSS REFERENCE TO A RELATED APPLICATION

This application is a Continuation of U.S. patent application Ser. No. 10/013,265 entitled, “ELECTRICALLY TUNABLE NOTCH FILTERS”, filed Dec. 10, 2001, which claimed the benefit of U.S. Provisional Application Ser. No. 60/254,841, filed Dec. 12, 2000.

### FIELD OF INVENTION

The present invention generally relates to radio frequency (RF) and microwave notch (bandstop) filters, and more particularly to tunable RF and microwave notch filters.

### BACKGROUND OF INVENTION

Electronic filters are widely used in radio frequency (RF) and microwave circuits. Tunable filters may significantly improve the performance of the circuits, and simplify the circuits. There are two well-known kinds of analog tunable filters used in RF applications, one is electrically tuned, usually by diode varactor, and the other is mechanically tuned. Mechanically tunable filters have the disadvantages of large size, low speed, and heavy weight. Diode-tuned filters that include conventional semiconductor varactor diodes suffer from low power handling capacity that is limited by intermodulation of the varactor, which causes signals to be generated at frequencies other than those desired. This intermodulation is caused by the highly non-linear response of conventional semiconductor varactors to voltage control.

Tunable filters for use in radio frequency circuits are well known. Examples of such filters can be found in U.S. Pat. Nos. 5,917,387, 5,908,811, 5,877,123, 5,869,429, 5,752,179, 5,496,795 and 5,376,907.

Varactors can be used as tunable capacitors in tunable filters. Common varactors used today are Silicon and GaAs based diodes. The performance of these varactors is defined by the capacitance ratio, Cₘₐₓ/Cₘᵢₙ, frequency range and figure of merit, or Q factor (1/tan δ) at the specified frequency range. The Q factors for these semiconductor varactors for frequencies up to 2 GHz are usually very good. However, at frequencies above 2 GHz, the Q factors of these varactors degrade rapidly. At 10 GHz the Q factors for these varactors are usually only about 30.

Another type of varactor is a tunable dielectric varactor, whose capacitance is tuned by applying a control voltage to change a dielectric constant in a tunable dielectric material. Tunable dielectric varactors have high Q factors, high power handling, low intermodulation distortion, wide capacitance range, and low cost.

Tunable ferroelectric materials are materials whose permittivity (more commonly called dielectric constant) can be varied by varying the strength of an electric field to which the materials are subjected. Even though these materials work in their paraelectric phase above the Curie temperature, they are conveniently called “ferroelectric” because they exhibit spontaneous polarization at temperatures below the Curie temperature. Tunable ferroelectric materials including barium-strontium titanate (BST) or BST composites have been the subject of several patents.

Varactors that utilize a thin film ferroelectric ceramic as a voltage tunable element in combination with a superconducting element have been described. For example, U.S. Pat. No. 5,640,042 discloses a thin film ferroelectric varactor having a carrier substrate layer, a high temperature superconducting layer deposited on the substrate, a thin film dielectric deposited on the metallic layer, and a plurality of metallic conductive means disposed on the thin film dielectric, which are placed in electrical contact with RF transmission lines in tuning devices. Another tunable capacitor using a ferroelectric element in combination with a superconducting element is disclosed in U.S. Pat. No. 5,721,194.

Commonly owned U.S. patent application Ser. No. 09/419,126, filed Oct. 15, 1999, and titled “Voltage Tunable Varactors And Tunable Devices Including Such Varactors”, discloses voltage tunable varactors and various devices that include such varactors. Commonly owned U.S. patent application Ser. No. 09/434,433, filed Nov. 4, 1999, and titled “Ferroelectric Varactor With Built-In DC Blocks” discloses voltage tunable varactors that include built-in DC blocking capacitors. Commonly owned U.S. patent application Ser. No. 09/844,832, filed Apr. 27, 2001, and titled “Voltage-Tuned Dielectric Varactors With Bottom Electrodes”, discloses additional voltage tunable varactors. Commonly owned U.S. patent application Ser. No. 09/660,309, filed Dec. 12, 2000, and titled “Dielectric Varactors With Offset Two-Layer Electrodes”, discloses other voltage tunable varactors. The varactors disclosed in these applications operate at room temperatures to provide a tunable capacitance.

Tunable filters that can utilize the varactors described in the commonly owned patent applications are described in another commonly owned patent application Ser. No. 09/457,943, filed Dec. 9, 1999 and titled “Electrically Tunable Filters With Dielectric Varactors”.

Filters for use in wireless communications products have been required to provide better performance with smaller size. Efforts have been made to develop new types of resonators, new coupling structures and new filter configurations. One of the techniques used to reduce the number of resonators is to add cross couplings between non-adjacent resonators to provide transmission zeros. As a result of these transmission zeros, the filter selectivity is improved. However, in order to achieve these transmission zeros, certain coupling patterns have to be followed. This impairs the size reduction effort. In some cases, it may be more feasible to add a notch filter to improve the attenuation in a certain frequency range, rather than making the filter complicated by adding cross couplings.

There is a need for a tunable notch filter, which can provide improved operation at radio and microwave frequencies.

### SUMMARY OF THE INVENTION

This invention provides a notch filter including a main transmission line, a coupling mechanism, and at least one electrically tunable resonator coupled to the transmission line through the coupling mechanism. The resonator can be tuned by using tunable dielectric varactors or microelectromechanical varactors. Telephone handsets that include notch filters are also included.

### BRIEF DESCRIPTION OF THE DRAWINGS

FIG. 1 is a schematic representation of a multi-resonator tunable notch filter constructed in accordance with this invention;

FIG. 2 is a graph of a multi-resonator notch filter response;

FIG. 3 is a plan view of a combline resonator that can be used in notch filters constructed in accordance with the invention;

FIG. 4 is a plan view of a hairpin resonator that can be used in notch filters constructed in accordance with the invention;

FIG. 5 is a plan view of a fin line resonator that can be used in notch filters constructed in accordance with the invention;

FIG. 6 is a schematic representation of another tunable notch filter constructed in accordance with the invention;

FIG. 7 is an isometric view of yet another notch tunable filter constructed in accordance with the invention;

FIG. 8 is a simplified block diagram of a mobile telephone handset that includes the filters of this invention;

FIG. 9 is a plan view of a tunable dielectric planar varactor;

FIG. 10 is a sectional view of the planar varactor of FIG. 9 taken along line 10-10;

FIG. 11 is a plan view of another tunable dielectric vertical varactor;

FIG. 12 is a sectional view of the vertical varactor of FIG. 111 taken along line 12-12;

FIG. 13 is a plan view of another tunable dielectric varactor;

FIG. 14 is a sectional view of the varactor of FIG. 13 taken along line 14-14;

FIG. 15 is a plan view of another tunable dielectric varactor;

FIG. 16 is a sectional view of the varactor of FIG. 15 taken along line 16-16;

FIG. 17 is a plan view of another tunable dielectric varactor;

FIG. 18 is a sectional view of the varactor of FIG. 17 taken along line 18-18;

FIG. 19 is a plan view of another tunable dielectric varactor;

FIG. 20 is a sectional view of the varactor of FIG. 19 taken along line 20-20;

FIG. 21 is a plan view of another tunable dielectric varactor;

FIG. 22 is a sectional view of the varactor of FIG. 21 taken along line 22-22;

FIG. 23 is a plan view of another tunable dielectric varactor;

FIG. 24 is a sectional view of the varactor of FIG. 23 taken along line 24-24;

FIG. 25 is a block diagram of a notch filter that can be constructed in accordance with this invention; and

FIG. 26 is a block diagram of another notch filter that can be constructed in accordance with this invention.

### DETAILED DESCRIPTION OF THE INVENTION

The present invention provides high performance and small size tunable notch filters for wireless communications applications, as well as other applications. The filters include tunable resonators that include tunable capacitors which can be tunable dielectric varactors or microelectromechanical (MEM) varactors. Compared with traditional semiconductor varactors, dielectric varactors have the merits of lower loss, higher power-handling, higher IP3, and faster tuning speed.

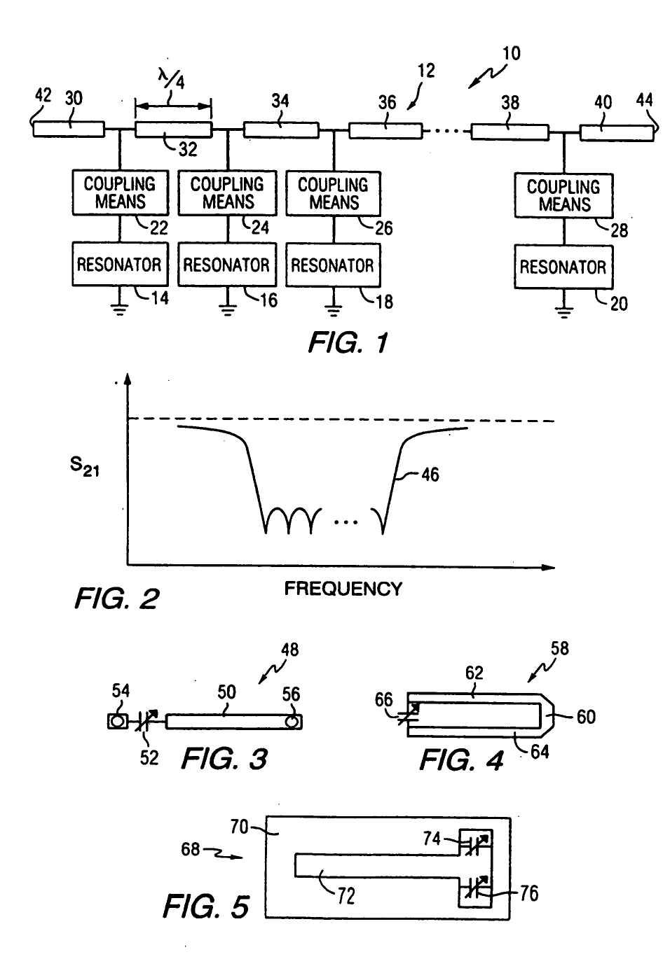

Referring to the drawings, FIG. 1 is a schematic representation of a multi-resonator notch filter constructed in accordance with this invention. As shown in FIG. 1, a notch filter 10, includes a main transmission line 12, a plurality of resonators 14, 16, 18 20, and some coupling structures 22, 24, 26, 28 that couple the resonators to the main transmission line. In the illustrated embodiment, the main transmission line includes a plurality of series connected line segments 30, 32, 34, 36, 38 and 40, each having a length of about ¼ wavelength of a signal at the center of a notch for which the filter was designed.

A first end of segment 30 serves as an input 42 and a first end of segment 40 serves as an output 44. The couplers are separated along the main transmission line by a distance equal to about a quarter wavelength. At least one of the resonators includes a tunable varactor that can be controlled to tune the resonant frequency. The resonant frequency of the resonators can be tuned to be in the stop band, but offset from each other. A larger number of resonators can provide a deeper notch or a wider stop band. FIG. 2 is a graph of a typical notch filter frequency response, as illustrated by curve 46.

The main transmission line and the coupling mechanism can be constructed using numerous different available structures. For example, the main transmission line can comprise a coaxial transmission line, a microstrip line, a stripline line, a rectangular waveguide, a coplanar waveguide, a ridged waveguide, etc. The coupling structures can be any of several known structures, for example, a capacitive probe, an inductive loop, an iris window, an evanescent waveguide piece, a slot, a hole, etc.

The resonators are the critical components in making the notch filter tunable. RF and microwave resonators usually include a transmission line with its two ends shorted or open. When it is shorted or open for both ends, it requires a half wavelength (λ/2) to resonate. Lines having lengths equal to multiple half wavelengths also work. When a line is shorted in one end and open at the other end, a quarter wavelength (λ/4) is required to resonate. Similarly, lines having lengths equal to multiple quarter wavelengths also work. Whether the lines are a half wavelength or a quarter wavelength, an end capacitor can be added to decrease the resonant frequency. By partially or fully replacing the end capacitor with a varactor, such as an electrically tunable dielectric varactor or MEM varactor, the resonant frequency of the resonator becomes electrically tunable. Examples of such resonators are shown in FIGS. 3, 4 and 5.

FIG. 3 is a plan view of a combline type of resonator 48, comprising a less than one-quarter wavelength short stub 50. One terminal of a tunable varactor 52 is connected to one end of the stub. The other terminal of the varactor is grounded, for example through a via 54, to a ground plane or other type of ground structure, not shown in this view. A connection point 56 is provided for connecting the other end of the stub to the main transmission line through a coupling device.

FIG. 4 is a plan view of a hairpin type resonator 58, which can also be called a loop resonator, that can be used in the filters of this invention. The hairpin resonator includes an end portion 60 connecting two linear sections 62 and 64. A tunable varactor 66 is connected between the ends of the linear sections to form a close loop. The hairpin resonator can be coupled to the main transmission line by placing end portion 60 near the main transmission line. The arms 62 and 64 would then lie perpendicular to the main transmission line.

FIG. 5 is a plan view of a fin line type resonator 68, which can also be used in the filters of this invention. The fin line resonator 68 would typically be used in a rectangular waveguide, not shown. A planar conductor 70 includes a T-shaped slot 72, with two varactors 74 and 76 connected across the slot and electrically in parallel to maintain a proper balance of the resonator structure.

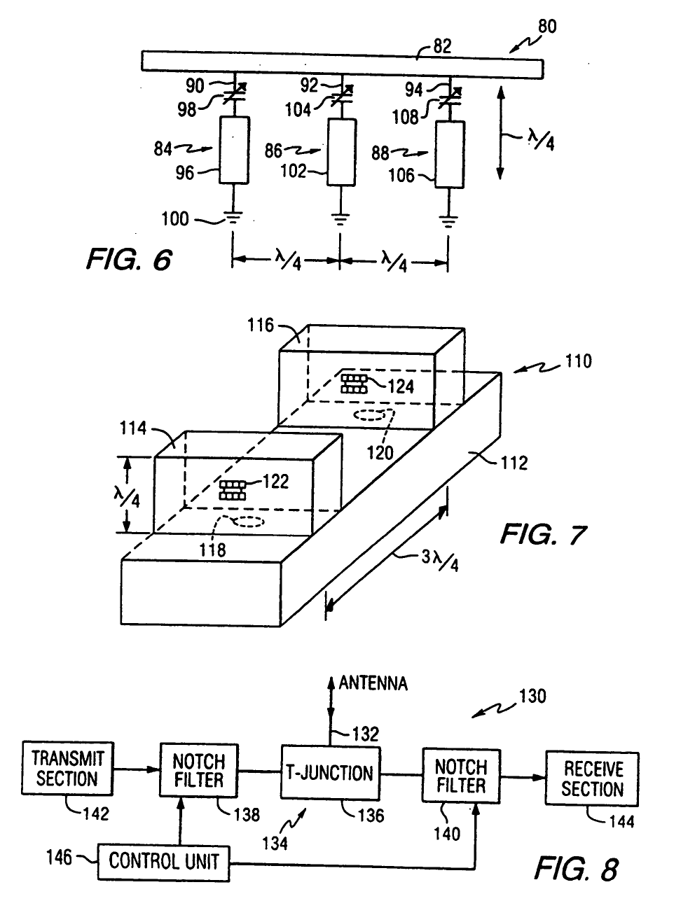

FIG. 6 is a schematic representation of another notch filter 80 constructed in accordance with the invention. Filter 80 includes a main microstrip transmission line 82 and three resonators 84, 86 and 88 coupled to the main transmission line by conductors 90, 92 and 94 respectively, at positions that are spaced about ¼ wavelength along the main transmission line. Resonator 84 includes a microstrip line 96 having a length of less than ¼ wavelength and a tunable varactor 98 connected between one end of the microstrip line 96 and the main transmission line. The other end of the microstrip line 96 is connected to ground 100. Resonator 86 includes a microstrip line 102 having a length of less than ¼ wavelength and a tunable varactor 104 connected between one end of the microstrip line 102 and the main transmission line. The other end of the microstrip line 202 is connected to ground. Resonator 88 includes a microstrip line 106 having a length of less than ¼ wavelength and a tunable varactor 108 connected between one end of the microstrip line 106 and the main transmission line. The other end of the microstrip line 106 is connected to ground.

The notch filter shown in FIG. 6 includes a main transmission line and three resonators. The resonators are typically shorted at one end (away from the main transmission line) and open at the other end (close to the transmission line). The length of the resonators is about ¼ wavelength at the center frequency of the notch. To make this notch filter tunable, there are two options. Option 1 is to put the varactor at the shorted end of the line, which will tune the center frequency of the notch, and option 2 is to put the varactor at the open end, between the resonator and transmission line. This will mainly tune the coupling between the resonator and the transmission line, although it will also tune the center frequency. The resonator shown in FIG. 3 has the varactor near the short, hence option 1, while the resonators shown in FIG. 6 have the varactors at the open end, potion 2. So, the coupling between the resonators and the line in FIG. 6 is capacitive, but variable (tunable), with the help of the varactors 98, 104, 108.

FIG. 7 is an isometric view of yet another notch tunable filter 110 constructed in accordance with the invention. Filter 110 includes a rectangular waveguide 112 and first and second waveguide stubs 114 and 116 positioned adjacent to the main waveguide and about ¾ wavelength apart. Waveguide stub 114 is coupled the main waveguide 112 by an iris 118. Waveguide stub 116 is coupled the main waveguide 112 by an iris 120. A tunable varactor 122 is mounted in waveguide stub 114, and a tunable varactor 124 is mounted in waveguide stub 116. There are many ways of mounting the varactors in the waveguide. For example, they could be mounted on a low loss dielectric support, or mounted on a metallic post provided inside of the waveguide, or, inserted in waveguide by a dielectric tape, or metallic septum, etc.

FIG. 6 illustrates a three-resonator planar notch filter 100, while FIG. 7 illustrates a two-resonator notch filter 110 in a rectangular waveguide structure. In the example of FIG. 7, the varactors are placed in the waveguide cavity in a proper location with a proper orientation.

FIG. 8 is a simplified block diagram of a mobile telephone handset 130 that includes the notch filters of this invention. The handset includes a connection 132 for an antenna, and a diplexer (or duplexer) 134 including a T-Junction 136, a first notch filter 138 and a second notch filter 140. The first notch filter 138 is connected to a transmit section 142 and the second notch filter is connected to a receive section 144. A control unit 146 provides control signals for controlling the varactors in the notch filters, thereby tuning the notch filters. The main function of duplexer is to provide isolation between the transmit and receive frequencies. That function can be achieved by using stop band filters, one at the receive frequency and one at the transmit frequency.

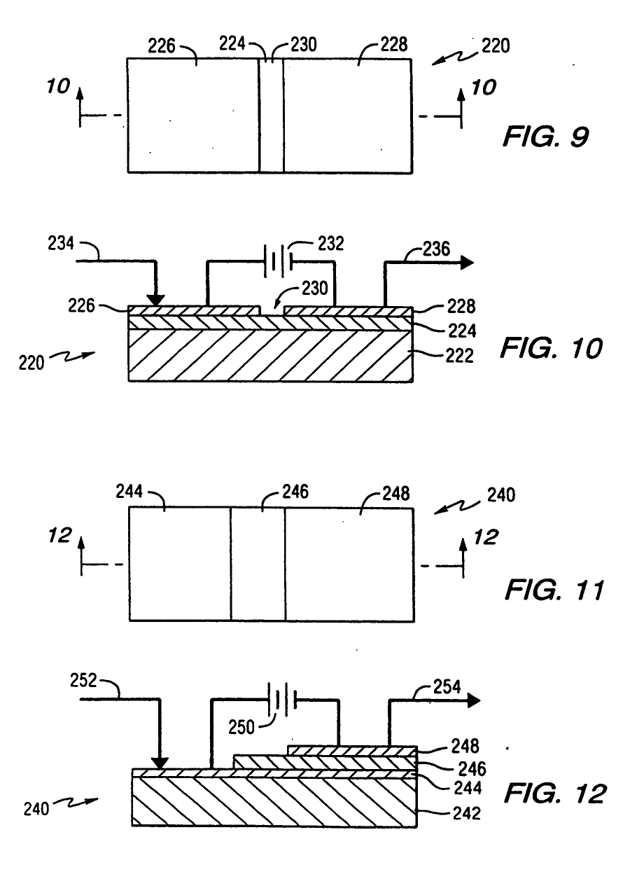

FIGS. 9 and 10 are top and cross-sectional views of a tunable dielectric planar varactor 220. The varactor includes a substrate 222 and a layer of tunable dielectric material 224 positioned on a surface of the substrate. A pair of electrodes 226 and 228 are positioned on a surface of the tunable dielectric layer opposite the substrate and separated by a gap 230. A DC bias voltage, as illustrated by voltage source 232, is applied to the electrodes to control the dielectric constant of the tunable dielectric material. An input 234 is provided for receiving an electrical signal and an output 236 is provided for delivering the signal.

FIGS. 11 and 12 are top and cross-sectional views of a tunable vertical varactor 240. The varactor includes a substrate 242 and a first electrode 244 positioned on a surface of the substrate. A layer of tunable dielectric material 246 is positioned on a surface of the first electrode opposite the substrate. A second electrode 248 is positioned on a surface of the tunable dielectric layer opposite the first electrode. A DC bias voltage, as illustrated by voltage source 250, is applied to the electrodes 244 and 248 to control the dielectric constant of the tunable dielectric material lying between the electrodes 244 and 248. An input 252 is provided for receiving an electrical signal and an output 254 is provided for delivering the signal.

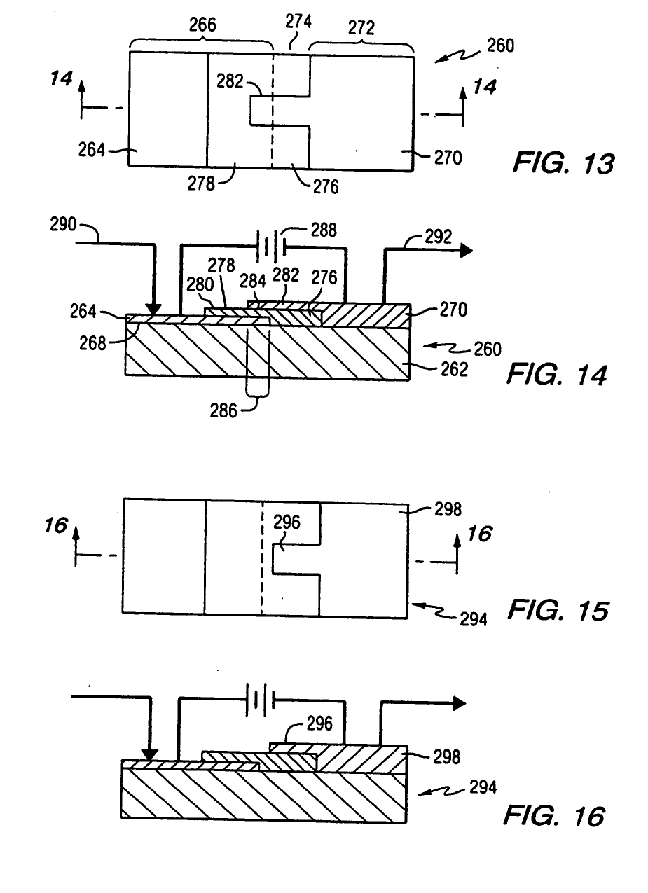

FIGS. 13 and 14 are top plan and cross-sectional views of a varactor 260. The varactor includes a substrate 262 and a first electrode 264 positioned on first portion 266 of a surface 268 of the substrate. A second electrode 270 is positioned on second portion 272 of the surface 268 of the substrate and separated from the first electrode to form a gap 274 therebetween. A tunable dielectric material 276 is positioned on the surface 268 of the substrate and in the gap between the first and second electrodes. A section 278 of the tunable dielectric material 276 extends along a surface 280 of the first electrode 264 opposite the substrate. The second electrode 270 includes a projection 282 that is positioned on a top surface 284 of the tunable dielectric layer opposite the substrate. The projection 282 has a rectangular shape and extends along the top surface 284 such that it vertically overlaps a portion 286 of the first electrode. The second electrode can be referred to as a “T-type” electrode. A DC bias voltage, as illustrated by voltage source 288, is applied to the electrodes 264 and 270 to control the dielectric constant of the tunable dielectric material lying between the electrodes 264 and 270. An input 290 is provided for receiving an electrical signal and an output 292 is provided for delivering the signal.

The tunable dielectric layer 276 can be a thin or thick film. The capacitance of the varactor of FIGS. 13 and 14 can be expressed as:

$$C = {ɛ}_{o} {ɛ}_{r} \frac{A}{t}$$

where C is capacitance of the capacitor; so is permittivity of free-space; εᵣ is dielectric constant (permittivity) of the tunable film; A is overlap area of the electrode 264 that is overlapped by electrode 270; and t is thickness of the tunable film in the overlapped section. An example of these parameters for 1 pF capacitor is: εᵣ=200; A=170 μm²; and t=0.3 μm. The horizontal distance (HD) along the surface of the substrate between the first and second electrodes is much greater than the thickness (t) of the dielectric film. Typically, the thickness of tunable film is <1 micrometer for thin films, and <5 micrometers for thick films, and the HD is greater than 50 micrometers. Theoretically, if HD is close to t, the capacitor will still work, but its capacitance would be slightly greater than that calculated from the above equation. However, from a processing technical view, it is difficult and not necessary to make HD close to t. Therefore, HD mainly depends on the processing used to fabricate the device, and is typically about >50 micrometers. In practice, we choose HD>10t.

The bottom electrode 264 can be deposited on the surface of the substrate by electron-beam, sputtering, electroplating or other metal film deposition techniques. The bottom electrode partially covers the substrate surface, which is typically done by etching processing. The thickness of the bottom electrode in one preferred embodiment is about 2 μm. The bottom electrode should be compatible with the substrate and the tunable films, and should be able to withstand the film processing temperature. The bottom electrode may typically be comprised of platinum, platinum-rhodium, ruthenium oxide or other materials that are compatible with the substrate and tunable films, as well as with the film processing. Another film may be required between the substrate and bottom electrode as an adhesion layer, or buffer layer for some cases, for example platinum on silicon can use a layer of silicon oxide, titanium or titanium oxide as a buffer layer.

The thin or thick film of tunable dielectric material 276 is then deposited on the bottom electrode and the rest of the substrate surface by techniques such as metal-organic solution deposition (MOSD or simply MOD), metal-organic chemical vapor deposition (MOCVD), pulse laser deposition (PLD), sputtering, screen printing and so on. The thickness of the thin or thick film that lies above the bottom electrode is preferably in range of 0.2 μm to 4 μm. Low loss and high tunability films should be selected to achieve high Q and high tuning of the varactor. These tunable dielectric films have dielectric constants of 2 to 1000, and tuning of greater than 20% with a loss tangent less than 0.005 at around 2 GHz. To achieve low capacitance, low dielectric constant (k) films should be selected. However, high k films usually show high tunability. The typical k range is about 100 to 500.

The second electrode 270 is formed by a conducting material deposited on the surface of the substrate and at least partially overlapping the tunable film, by using similar processing as set forth above for the bottom electrode. Metal etching processing can be used to achieve specific top electrode patterns. The etching processing may be dry or wet etching. The top electrode materials can be gold, silver, copper, platinum, ruthenium oxide or other conducting materials that are compatible with the tunable films. Similar to the bottom electrode, a buffer layer for the top electrode could be necessary, depending on the electrode-tunable film system. Finally, a part of the tunable film should be etched away to expose the bottom electrode.

The substrate layer in the described varactors may be comprised of MgO, alumina (AL₂O₃), LaAlO₃, sapphire, quartz, silicon, gallium arsenide, and other materials that are compatible with the various tunable films and the electrodes, as well as the processing used to produce the tunable films and the electrodes.

For a certain thickness and dielectric constant of the tunable dielectric film, the pattern and arrangement of the top electrode are key parameters in determining the capacitance of the varactor. In order to achieve low capacitance, the top electrode may have a small overlap (as shown in FIGS. 13 and 14) or no overlap with the bottom electrode. FIGS. 15 and 16 are top plan and cross-sectional views of a varactor 294 having a T-type top electrode with no overlap electrode area. The structural elements of the varactor of FIGS. 15 and 16 are similar to the varactor of FIGS. 13 and 14, except that the rectangular projection 296 on electrode 298 is smaller and does not overlap electrode 264. Varactors with no electrode overlap area may need more tuning voltage than those in which the electrodes overlap.

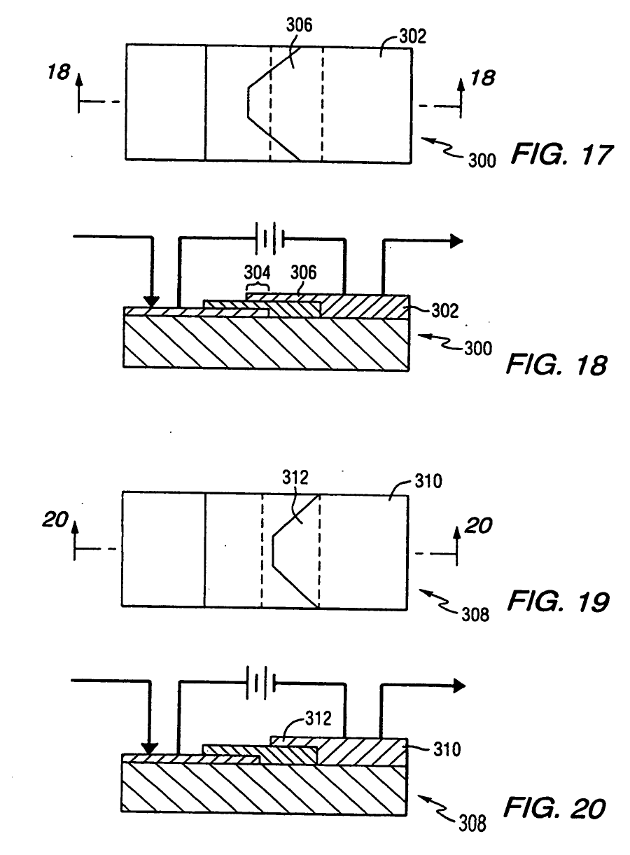

FIGS. 17 and 18 are top plan and cross-sectional views of a varactor 300 having a top electrode 302 with a trapezoid-type projection 306 and an overlapped electrode area 304. The structural elements of the varactor of FIGS. 17 and 18 are similar to the varactor of FIGS. 13 and 14, except that the projection 306 on electrode 302 has a trapezoidal shape. Since the projection on the T-type electrode of the varactor of FIGS. 19 and 20 is relatively narrow, the trapezoid-type top electrode of the varactor of FIGS. 17 and 18 is less likely to break, compared to the T-type pattern varactor. FIGS. 19 and 20 are top plan and cross-sectional views of a varactor 308 having a trapezoid-type electrode 310 having a smaller projection 312 with no overlap area of electrodes, to obtain lower capacitance.

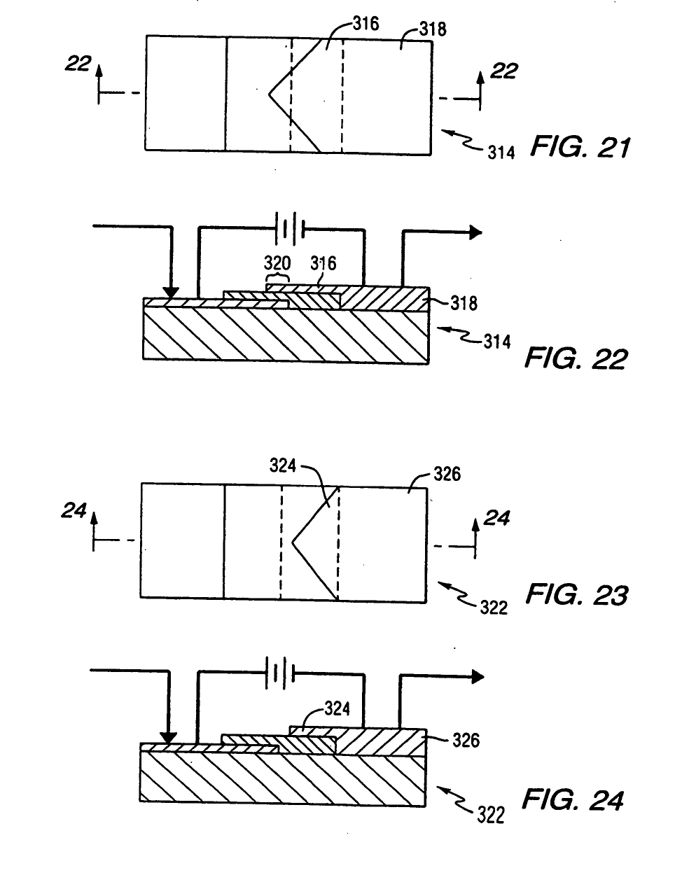

FIGS. 20 and 21 are top plan and cross-sectional views of a varactor 314 having a triangle-type projection 316 on the top electrode 318 that overlaps a portion of the bottom electrode at region 320. Using a triangle projection on the top electrode may make it easier to reduce the overlap area of the electrodes. FIGS. 23 and 24 are top plan and cross-sectional views of a varactor 322 having triangle-type projection 324 on the top electrode 326 that does not overlap the bottom electrode.

Tunable dielectric materials have been described in several patents. Barium strontium titanate (BaTiO₃—SrTiO₃), also referred to as BSTO, is used for its high dielectric constant (200-6,000) and large change in dielectric constant with applied voltage (25-75 percent with a field of 2 Volts/micron). Tunable dielectric materials including barium strontium titanate are disclosed in U.S. Pat. No. 5,312,790 to Sengupta, et al. entitled “Ceramic Ferroelectric Material”; U.S. Pat. No. 5,427,988 by Sengupta, et al. entitled “Ceramic Ferroelectric Composite Material-BSTO-MgO”; U.S. Pat. No. 5,486,491 to Sengupta, et al. entitled “Ceramic Ferroelectric Composite Material—BSTO-ZrO₂”; U.S. Pat. No. 5,635,434 by Sengupta, et al. entitled “Ceramic Ferroelectric Composite Material-BSTO-Magnesium Based Compound”; U.S. Pat. No. 5,830,591 by Sengupta, et al. entitled “Multilayered Ferroelectric Composite Waveguides”; U.S. Pat. No. 5,846,893 by Sengupta, et al. entitled “Thin Film Ferroelectric Composites and Method of Making”; U.S. Pat. No. 5,766,697 by Sengupta, et al. entitled “Method of Making Thin Film Composites”; U.S. Pat. No. 5,693,429 by Sengupta, et al. entitled “Electronically Graded Multilayer Ferroelectric Composites”; U.S. Pat. No. 5,635,433 by Sengupta entitled “Ceramic Ferroelectric Composite Material BSTO-ZnO”; U.S. Pat. No. 6,074,971 by Chiu et al. entitled “Ceramic Ferroelectric Composite Materials with Enhanced Electronic Properties BSTO-Mg Based Compound-Rare Earth Oxide”. These patents are incorporated herein by reference. The materials shown in these patents, especially BSTO-MgO composites, show low dielectric loss and high tunability. Tunability is defined as the fractional change in the dielectric constant with applied voltage.

Barium strontium titanate of the formula BaₓSr₁₋ₓTiO₃ is a preferred electronically tunable dielectric material due to its favorable tuning characteristics, low Curie temperatures and low microwave loss properties. In the formula BaₓSr₁₋ₓTiO₃, x can be any value from 0 to 1, preferably from about 0.15 to about 0.6. More preferably, x is from 0.3 to 0.6.

Other electronically tunable dielectric materials may be used partially or entirely in place of barium strontium titanate. An example is BaₓCa₁₋ₓTiO₃, where x is in a range from about 0.2 to about 0.8, preferably from about 0.4 to about 0.6. Additional electronically tunable ferroelectrics include PbₓZr₁₋ₓTiO₃ (PZT) where x ranges from about 0.0 to about 1.0, PbₓZr₁₋ₓSrTiO₃ where x ranges from about 0.05 to about 0.4, KTaₓNb₁₋ₓO₃ where x ranges from about 0.0 to about 1.0, lead lanthanum zirconium titanate (PLZT), PbTiO₃, BaCaZrTiO₃, NaNO₃, KNbO₃, LiNbO₃, LiTaO₃, PbNb₂O₆, PbTa₂O₆, KSr(NbO₃) and NaBa₂(NbO₃)₅ KH₂PO₄, and mixtures and compositions thereof. Also, these materials can be combined with low loss dielectric materials, such as magnesium oxide (MgO), aluminum oxide (Al₂O₃), and zirconium oxide (ZrO₂), and/or with additional doping elements, such as manganese (MN), iron (Fe), and tungsten (W), or with other alkali earth metal oxides (i.e. calcium oxide, etc.), transition metal oxides, silicates, niobates, tantalates, aluminates, zirconnates, and titanates to further reduce the dielectric loss.

In addition, the following U.S. patent applications, assigned to the assignee of this application, disclose additional examples of tunable dielectric materials: U.S. application Ser. No. 09/594,837 filed Jun. 15, 2000, entitled “Electronically Tunable Ceramic Materials Including Tunable Dielectric and Metal Silicate Phases”; U.S. application Ser. No. 09/768,690 filed Jan. 24, 2001, entitled “Electronically Tunable, Low-Loss Ceramic Materials Including a Tunable Dielectric Phase and Multiple Metal Oxide Phases”; U.S. application Ser. No. 09/882,605 filed Jun. 15, 2001, entitled “Electronically Tunable Dielectric Composite Thick Films And Methods Of Making Same”; U.S. application Ser. No. 09/834,327 filed Apr. 13, 2001, entitled “Strain-Relieved Tunable Dielectric Thin Films”; and U.S. Provisional Application Ser. No. 60/295,046 filed Jun. 1, 2001 entitled “Tunable Dielectric Compositions Including Low Loss Glass Frits”. These patent applications are incorporated herein by reference.

The tunable dielectric materials can also be combined with one or more non-tunable dielectric materials. The non-tunable phase(s) may include MgO, MgAl₂O₄, MgTiO₃, Mg₂SiO₄, CaSiO₃, MgSrZrTiO₆, CaTiO₃, Al₂O₃, SiO₂ and/or other metal silicates such as BaSiO₃ and SrSiO₃. The non-tunable dielectric phases may be any combination of the above, e.g., MgO combined with MgTiO₃, MgO combined with MgSrZrTiO₆, MgO combined with Mg₂SiO₄, MgO combined with Mg₂SiO₄, Mg₂SiO₄ combined with CaTiO₃ and the like.

Additional minor additives in amounts of from about 0.1 to about 5 weight percent can be added to the composites to additionally improve the electronic properties of the films. These minor additives include oxides such as zirconnates, tannates, rare earths, niobates and tantalates. For example, the minor additives may include CaZrO₃, BaZrO₃, SrZrO₃, BaSnO₃, CaSnO₃, MgSnO₃, Bi₂O₃/2SnO₂, Nd₂O₃, Pr₇₀₁₁, Yb₂O₃, Ho₂O₃, La₂O₃, MgNb₂O₆, SrNb₂O₆, BaNb₂O₆, MgTa₂O₆, BaTa₂O₆ and Ta₂O₃.

Thick films of tunable dielectric composites can comprise Ba₁₋ₓSrₓTiO₃, where x is from 0.3 to 0.7 in combination with at least one non-tunable dielectric phase selected from MgO, MgTiO₃, MgZrO₃, MgSrZrTiO₆, Mg₂SiO₄, CaSiO₃, MgAl₂O₄, CaTiO₃, Al₂O₃, SiO₂, BaSiO₃ and SrSiO₃. These compositions can be BSTO and one of these components, or two or more of these components in quantities from 0.25 weight percent to 80 weight percent with BSTO weight ratios of 99.75 weight percent to 20 weight percent.

The electronically tunable materials can also include at least one metal silicate phase. The metal silicates may include metals from Group 2A of the Periodic Table, i.e., Be, Mg, Ca, Sr, Ba and Ra, preferably Mg, Ca, Sr and Ba. Preferred metal silicates include Mg₂SiO₄, CaSiO₃, BaSiO₃ and SrSiO₃. In addition to Group 2A metals, the present metal silicates may include metals from Group 1A, i.e., Li, Na, K, Rb, Cs and Fr, preferably Li, Na and K. For example, such metal silicates may include sodium silicates such as Na₂SiO₃ and NaSiO₃-5H₂O, and lithium-containing silicates such as LiAlSiO₄, Li₂SiO₃ and Li₄SiO₄. Metals from Groups 3A, 4A and some transition metals of the Periodic Table may also be suitable constituents of the metal silicate phase. Additional metal silicates may include Al₂Si₂O₇, ZrSiO₄, KalSi₃O₈, NaAlSi₃O₈, CaAl₂Si₂O₈, CaMgSi₂O₆, BaTiSi₃O₉ and Zn₂SiO₄. The above tunable materials can be tuned at room temperature by controlling an electric field that is applied across the materials.

In addition to the electronically tunable dielectric phase, the electronically tunable materials can include at least two additional metal oxide phases. The additional metal oxides may include metals from Group 2A of the Periodic Table, i.e., Mg, Ca, Sr, Ba, Be and Ra, preferably Mg, Ca, Sr and Ba. The additional metal oxides may also include metals from Group 1A, i.e., Li, Na, K, Rb, Cs and Fr, preferably Li, Na and K. Metals from other Groups of the Periodic Table may also be suitable constituents of the metal oxide phases. For example, refractory metals such as Ti, V, Cr, Mn, Zr, Nb, Mo, Hf, Ta and W may be used. Furthermore, metals such as Al, Si, Sn, Pb and Bi may be used. In addition, the metal oxide phases may comprise rare earth metals such as Sc, Y, La, Ce, Pr, Nd and the like.

The additional metal oxides may include, for example, zirconnates, silicates, titanates, aluminates, stannates, niobates, tantalates and rare earth oxides. Preferred additional metal oxides include Mg₂SiO₄, MgO, CaTiO₃, MgZrSrTiO₆, MgTiO₃, MgAl₂O₄, WO₃, SnTiO₄, ZrTiO₄, CaSiO₃, CaSnO₃, CaWO₄, CaZrO₃, MgTa₂O₆, MgZrO₃, MnO₂, PbO, Bi₂O₃ and La₂O₃. Particularly preferred additional metal oxides include Mg₂SiO₄, MgO, CaTiO₃, MgZrSrTiO₆, MgTiO₃, MgAl₂O₄, MgTa₂O₆ and MgZrO₃.

The additional metal oxide phases are typically present in total amounts of from about 1 to about 80 weight percent of the material, preferably from about 3 to about 65 weight percent, and more preferably from about 5 to about 60 weight percent. In one preferred embodiment, the additional metal oxides comprise from about 10 to about 50 total weight percent of the material. The individual amount of each additional metal oxide may be adjusted to provide the desired properties. Where two additional metal oxides are used, their weight ratios may vary, for example, from about 1:100 to about 100:1, typically from about 1:10 to about 10:1 or from about 1:5 to about 5:1. Although metal oxides in total amounts of from 1 to 80 weight percent are typically used, smaller additive amounts of from 0.01 to 1 weight percent may be used for some applications.

The additional metal oxide phases can include at least two Mg-containing compounds. In addition to the multiple Mg-containing compounds, the material may optionally include Mg-free compounds, for example, oxides of metals selected from Si, Ca, Zr, Ti, Al and/or rare earths. In another embodiment, the additional metal oxide phases may include a single Mg-containing compound and at least one Mg-free compound, for example, oxides of metals selected from Si, Ca, Zr, Ti, Al and/or rare earths. The high Q tunable dielectric capacitor utilizes low loss tunable substrates or films.

To construct a tunable device, the tunable dielectric material can be deposited onto a low loss substrate. In some instances, such as where thin film devices are used, a buffer layer of tunable material, having the same composition as a main tunable layer, or having a different composition can be inserted between the substrate and the main tunable layer. The low loss dielectric substrate can include magnesium oxide (MgO), aluminum oxide (Al₂O₃), and lanthium oxide (LaAl₂O₃).

Compared to voltage-controlled semiconductor diode varactors, voltage-controlled tunable dielectric capacitors have higher Q factors, lower loss, higher power-handling, and higher IP3, especially at higher frequencies (>10 GHz).

Tunable dielectric capacitors (dielectric varactors) or microelectromechanical (MEM) varactors can be used as the tunable elements in the notch filters of this invention. At least two varactor topologies of MEM varactors can be used, parallel plate and interdigital. In the parallel plate structure, one plate is suspended at a distance from another plate by suspension springs. This distance can vary in response to electrostatic force between the two parallel plates induced by an applied bias voltage. In the interdigital configuration, the effective area of the capacitor is varied by moving the fingers comprising the capacitor in and out and changing its capacitance value. MEM varactors have lower Q than their dielectric counterpart, especially at higher frequencies, but can be used in low frequency applications.

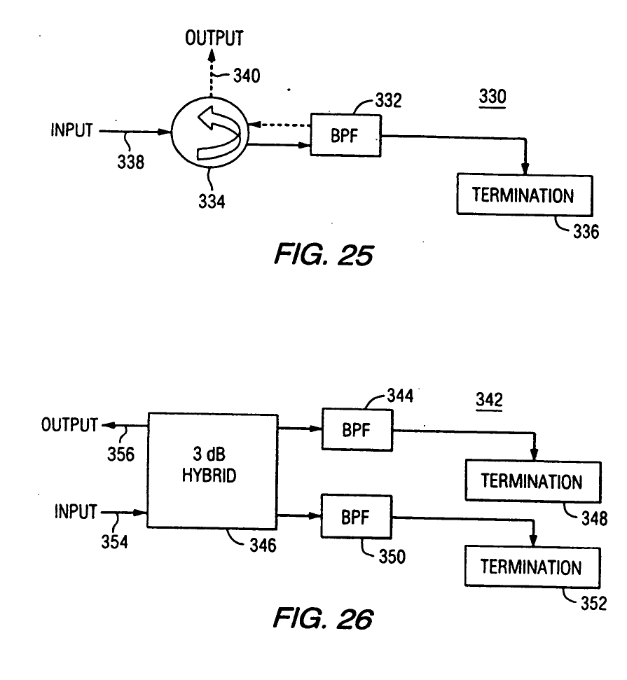

A notch filter can also be constructed in accordance with this invention by converting a bandpass filter with either a circulator or a 3 dB hybrid. FIG. 25 is a block diagram of a notch filter 330 that can be constructed in accordance with this invention. The filter of FIG. 25 includes a bandpass filter 332 connected between a circulator 334 and a termination 336. A input 338 and an output 340 are connected to the circulator. FIG. 26 is a block diagram of another notch filter 342 that can be constructed in accordance with this invention. The filter of FIG. 26 includes a first bandpass filter 344 connected between a 3 dB hybrid 346 and a termination 348, and a second bandpass filter 350 connected between the 3 dB hybrid 346 and a termination 352. A input 354 and an output 356 are connected to the 3 dB hybrid. In both cases the bandpass filters are tuned at the notch frequency fₒ, and the other frequencies are reflected from the filters and bounced back towards the output. So, at the output port we will have other frequencies that were originally input to the device, minus fₒ.

The invention provides compact, high performance, low loss, and low cost tunable notch filters. In the preferred embodiment, the tunable resonators include tunable dielectric varactors or MEM varactors. These compact notch filters are suitable for wireless communication applications to eliminate unwanted signals in communication systems, to make the notch filter electrically tunable, and to reduce system costs. The tunable notch filter can significantly improve the communication system quality.

While the present invention has been described in terms of its preferred embodiments, those skilled in the art will recognize that various other filters can be constructed in accordance with the invention as defined by the claims.

1. A notch filter comprising:
a main transmission line;
a first coupling mechanism; and
a first electrically tunable resonator coupled to the main transmission line through the first coupling mechanism wherein the first electrically tunable resonator includes a voltage tunable dielectric varactor incorporating tunable dielectric material.

2. A notch filter according to claim 1, wherein the first tunable varactor comprises:
a substrate having a first dielectric constant and having a generally planar surface;
a tunable dielectric layer positioned on the generally planar surface of the substrate, the tunable dielectric layer having a second dielectric constant greater than said first dielectric constant; and
first and second electrodes positioned on a surface of the tunable dielectric layer opposite the generally planar surface of the substrate, said first and second electrodes being separated to form a gap therebetween.

3. A notch filter according to claim 1, wherein the first coupling mechanism comprises one of:
a first capacitive probe, a first inductive loop, a first iris window, a first evanescent waveguide piece, a first slot, and a first hole.

4. A notch filter according to claim 1, wherein the main transmission line comprises one of:
a coaxial transmission line, a microstrip line, a stripline line, a rectangular waveguide, a coplanar waveguide, and a ridged waveguide.

5. A notch filter according to claim 1, further comprising:
a second coupling mechanism; and
a second electrically tunable resonator coupled to the main transmission line through the second coupling mechanism, wherein the first and second coupling mechanisms are spaced ¼ wavelength apart at an operating frequency of the filter.

6. A notch filter according to claim 5, wherein the second electrically tunable resonator includes a second tunable dielectric varactor or a second microelectromechanical varactor.

7. A notch filter according to claim 5, wherein the second tunable varactor comprises:
a substrate having a first dielectric constant and having a generally planar surface;
a tunable dielectric layer positioned on the generally planar surface of the substrate, the tunable dielectric layer having a second dielectric constant greater than said first dielectric constant; and
first and second electrodes positioned on a surface of the tunable dielectric layer opposite the generally planar surface of the substrate, said first and second electrodes being separated to form a gap therebetween.

8. A notch filter according to claim 5, wherein the second coupling mechanism comprises one of:
a second capacitive probe, a second inductive loop, a second iris window, a second evanescent waveguide piece, a second slot, and a second hole.

9. A method comprising:
providing a notch filter comprising a main transmission line, a first coupling mechanism, and a first electrically tunable resonator coupled to the main transmission line through the first coupling mechanism, wherein the first electrically tunable resonator includes a voltage tunable dielectric varactor incorporating tunable dielectric material; and
connecting the notch filter to a circuit.

10. The method of claim 9, wherein the first electrically tunable resonator comprises a first tunable dielectric varactor comprising:
a substrate having a first dielectric constant and having a generally planar surface;
a tunable dielectric layer positioned on the generally planar surface of the substrate, the tunable dielectric layer having a second dielectric constant greater than said first dielectric constant; and
first and second electrodes positioned on a surface of the tunable dielectric layer opposite the generally planar surface of the substrate, said first and second electrodes being separated to form a gap therebetween.

11. The method of claim 9, wherein the first electrically tunable resonator comprises a tunable dielectric material with a dielectric range from constants of 2 to 1000, and tuning of greater than 20% with a loss tangent less than 0.005 at around 2 GHz.

12. The method of claim 9, wherein the first coupling mechanism comprises one of:
a first capacitive probe, a first iris window, a first evanescent waveguide piece, a first slot, and a first hole.

13. The method of claim 9, wherein the main transmission line comprises one of wherein the main transmission line comprises one of a coaxial transmission line, a stripline line, a rectangular waveguide, a coplanar waveguide, and a ridged waveguide.

14. The method of claim 9, further comprising:
connecting a second electrically tunable resonator via a second coupling mechanism to said main transmission line, wherein the first and second coupling mechanisms are spaced ¼ wavelength apart at an operating frequency of the filter.

15. The method of claim 9, further comprising:
connecting a second electrically tunable resonator via a second coupling mechanism to said main transmission line, wherein the second electrically tunable resonator comprises a second tunable dielectric varactor.

16. The method of claim 15, wherein the second tunable dielectric varactor comprises:
a substrate having a first dielectric constant and having a generally planar surface; a tunable dielectric layer positioned on the generally planar surface of the substrate, the tunable dielectric layer having a second dielectric constant greater than said first dielectric constant; and
first and second electrodes positioned on a surface of the tunable dielectric layer opposite the generally planar surface of the substrate, said first and second electrodes being separated to form a gap therebetween.
